(19) United States
(12) Patent Application Publication
(10) Pub. No.: US 2008/0090343 A1
(43) Pub. Date: Apr. 17, 2008

(54) METHOD FOR MANUFACTURING THIN FILM TRANSISTOR ARRAY PANEL

(75) Inventors: In-Ho Song, Cheonan-si (KR); Won Song, Cheonan-si (KR); Sang-Gab Kim, Seoul (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 11/752,948

(22) Filed: May 24, 2007

(30) Foreign Application Priority Data
Oct. 17, 2006 (KR) 10-2006-0100750

(51) Int. Cl. H01L 21/336

(52) U.S. Cl. 438/160; 257/E21.414

(57) ABSTRACT

A method of manufacturing a thin film transistor array panel includes forming a gate line on a substrate; sequentially forming a gate insulating layer, a semiconductor layer, and a conductive layer on the gate line; forming a photosensitive film on the conductive layer; forming a first photosensitive film pattern including a first region and a second region having a lesser thickness than the first region by patterning the photosensitive film; forming a data pattern by etching the conductive layer using the first photosensitive film pattern as a mask; forming a second photosensitive film pattern by ashing the first photosensitive film pattern to partially remove the first photosensitive film; forming a semiconductor pattern by etching the semiconductor layer using the second photosensitive film pattern as a mask; and forming a source and drain electrode by etching the data pattern exposed in the second region of the second photosensitive film pattern.

This application claims priority to Korean Patent Application No. 10-2006-0100750, filed on Oct. 17, 2006, and all the benefits accruing therefrom under 35 U.S.C. § 119, the contents of which in its entirety are herein incorporated by reference.

### BACKGROUND OF THE INVENTION

(a) Field of the Invention

The present invention relates to a method of forming a pattern using an etching process, and a manufacturing method of a thin film transistor (TFT) array panel using the same.

(b) Description of the Related Art

Liquid crystal displays “LCDs” are one of the most widely used flat panel displays, and includes two panels provided with electrodes, as well as a liquid crystal “LC” layer interposed therebetween. The LCD adjusts an amount of light transmitted by applying voltages to the electrodes in order to rearrange LC molecules in the LC layer.

Among the various types of LCDs currently available, an LCD having two panels respectively provided with field-generating electrodes represents one of the most common. Among this particular type of LCDs, an LCD wherein one panel has a plurality of pixel electrodes arranged in a matrix and the other panel has a common electrode covering the entire panel surface is widely used. The LCD displays images by applying different voltages to the respective pixel electrodes. For this purpose, TFTs having three terminals to switch the voltages applied to the pixel electrodes are connected to the respective pixel electrodes. In addition, gate lines to transmit signals for controlling the TFTs and data lines to transmit voltages applied to the pixel electrodes are formed on a panel (hereinafter referred to as a “TFT array panel”).

A TFT functions as a switching element for transmitting or blocking an image signal from the data line to the pixel electrode in response to a scanning signal from the gate line. The TFT is applied to an active matrix organic light emitting diode display, which is a self-emissive display device, as a switching element for controlling respective light emitting elements.

A TFT array panel comprises a plurality of thin films including a gate layer, a data layer, and a semiconductor layer. These thin films are formed into separate patterns using separate masks. However, processes such as illuminating, developing, and etching are needed whenever a mask is added, which results in a significant increase in manufacturing cost and time.

The semiconductor layer and the data conductive layer are each formed using a photosensitive film mask, a portion of which corresponds to a channel portion between a source electrode and a data electrode of the data layer having an upper part that is formed lower than other parts of the mask. Then, ashing is performed so that the portion of the photosensitive film mask corresponding to the channel portion is completely removed. Using this photosensitive film mask as an etching blocking layer, the data conductive layer is then etched in a conventional manner to form source electrodes and drain electrodes.

However, in such a manufacturing process of a TFT array panel as described above, the forming step of the semiconductor layer and the data conductive layer, the ashing process of the photosensitive film mask, and the forming step of the source electrodes and the drain electrodes are each performed in different tool chambers. As a result, the process steps are complicated and the process time is lengthy.

Furthermore, a natural oxide film is formed on the entire upper surface of the substrate by the ashing process of the photosensitive film mask, which causes incomplete removal of the data conductive layer existing on the channel portion such that a short circuit between the source electrode and the drain electrode may result.

### BRIEF SUMMARY OF THE INVENTION

Aspects of the present invention prevent short circuiting between a source electrode and a drain electrode of an LCD device, as well reduce the processing time thereof.

An exemplary embodiment of the present invention provides a method of manufacturing a thin film transistor array panel including: forming a gate line on a substrate; sequentially forming a gate insulating layer, a semiconductor layer, and a conductive layer on the gate line; forming a photosensitive film on the conductive layer; forming a first photosensitive film pattern including a first region and a second region that has a lesser thickness than the first region by patterning the photosensitive film; forming a data pattern by etching the conductive layer using the first photosensitive film pattern as a mask; forming a second photosensitive film pattern by ashing the first photosensitive film pattern to partially remove the first photosensitive film by as much as the thickness of the second region; forming a semiconductor pattern by etching the semiconductor layer using the second photosensitive film pattern as a mask; and forming a source electrode and a drain electrode by etching the data pattern exposed in the second region of the second photosensitive film pattern.

In one aspect, the first region may be a region corresponding to the location of a subsequently formed a data wire.

The second region may be a region corresponding to the location of a channel of a subsequently formed thin film transistor.

The conductive layer may be dry etched using a fluorine-based gas including sulfur hexafluoride (SF₆).

The ashing of the first photosensitive film pattern may be performed through an oxygen (O₂) plasma process.

The semiconductor layer may be dry etched using a fluorine-based gas including sulfur hexafluoride (SF₆) gas and a chlorine-based gas including chlorine (Cl₂) gas or hydrogen chloride (HCl) gas.

A gas mixture of two or more of helium (He) gas, neon (Ne) gas, and oxygen (O₂) gas may be added as a carrier gas for facilitating the dry etching process.

In forming the semiconductor pattern, a gas mixture of a sulfur hexafluoride (SF₆) or boron trichloride (BCl₃) gas and a chlorine (Cl₂) or hydrogen chloride (HCl) gas may be used, and a gas mixture of two or more of helium (He) gas, neon (Ne) gas, and oxygen (O₂) gas may be used as a carrier gas.

The method may further include forming a passivation layer on the gate insulating layer, the source electrode and the drain electrode, and forming a pixel electrode on the passivation layer.

Another exemplary embodiment of the present invention provides a method for manufacturing a thin film transistor array panel including: forming a gate line on a substrate; sequentially forming a gate insulating layer, an intrinsic semiconductor layer, and an impurity-doped semiconductor layer on the gate line; sequentially forming a lower molybdenum (Mo) layer, an intermediate aluminum (Al) layer, and an upper molybdenum (Mo) layer on the impurity-doped semiconductor layer to form a triple-layered conductive layer; forming a photosensitive film on the upper molybdenum (Mo) layer; forming a first photosensitive film pattern including a first region and a second region that has a lesser thickness than the first region by patterning the photosensitive film; forming a data pattern by etching the triple-layered conductive layer using the first photosensitive film pattern as a mask; forming a second photosensitive film pattern by ashing the first photosensitive film pattern to partially remove the first photosensitive film by as much as the thickness of the second region; forming an impurity-doped semiconductor pattern and an intrinsic semiconductor by etching the impurity-doped semiconductor layer and the intrinsic semiconductor layer using the second photosensitive film pattern as a mask; forming a source electrode and a drain electrode by etching the data pattern exposed in the second region of the second photosensitive film pattern; and forming a contact member layer by etching the impurity-doped semiconductor pattern.

In etching the impurity-doped semiconductor layer and the intrinsic semiconductor layer, the upper molybdenum (Mo) layer that is exposed and constitutes the data pattern may be removed, and the aluminum (Al) layer disposed under the removed upper molybdenum (Mo) layer may be removed.

The first region may be a region corresponding to the location of a subsequently formed a data wire, and the second region may be a region corresponding to the location of a channel of a subsequently formed thin film transistor.

The etching of the triple-layered conductive layer using the first photosensitive film pattern as a mask may be performed with a fluorine-based gas including sulfur hexafluoride (SF₆) gas.

The ashing of the first photosensitive film pattern may be performed through an oxygen (O₂) plasma process.

The etching of the impurity-doped semiconductor layer and the intrinsic semiconductor layer may be performed by a dry etching process using a fluorine-based gas including sulfur hexafluoride (SF₆) gas and a chlorine-based gas including chlorine (Cl₂) gas or hydrogen chloride (HCl) gas.

A gas mixture of two or more of helium (He) gas, neon (Ne) gas, and oxygen (O₂) gas may be added as a carrier gas for facilitating the dry etching process.

In etching the data pattern, a gas mixture of boron trichloride (BCl₃) gas and a chlorine (Cl₂) or hydrogen chloride (HCl) gas may be used, and a gas mixture of two or more of helium (He) gas, neon (Ne) gas, and oxygen (O₂) gas may be used as a carrier gas.

### BRIEF DESCRIPTION OF THE DRAWINGS

The above and other aspects and features of the present invention will become more apparent by describing in detail exemplary embodiments thereof with reference to the attached drawings, in which:

FIG. 1 is a layout view of a TFT array panel according to an exemplary embodiment of the present invention;

FIG. 2 and FIG. 3 are cross-sectional views of the TFT array panel shown in FIG. 1 taken along the line II-II′ and the line III-III′, respectively;

FIG. 4 is a layout view of the TFT array panel shown in FIG. 1 in an intermediate step of a manufacturing method thereof according to an exemplary embodiment of the present invention;

FIG. 5 and FIG. 6 are cross-sectional views of the TFT array panel shown in FIG. 4 taken along the line V-V′ and the line VI-VI′, respectively;

FIG. 7 to FIG. 16 are cross-sectional views sequentially illustrating steps following the step shown in FIG. 4 to FIG. 6 of the manufacturing method of the TFT array panel;

FIG. 17 is a layout view of the TFT array panel in a step following the step shown in FIG. 15 and FIG. 16;

FIG. 18 and FIG. 19 are cross-sectional views of the TFT array panel shown in FIG. 17 taken along the line XVIII-XVIII′ and the line XIX-XIX′;

FIG. 20 is a layout view of the TFT array panel in a step following the step shown in FIG. 17 to FIG. 19; and

FIG. 21 and FIG. 22 are cross-sectional views of the TFT array panel shown in FIG. 20 taken along the line XXI-XXI′ and the line XXII-XXII′.

### DETAILED DESCRIPTION OF THE INVENTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Exemplary embodiments of the present invention will hereinafter be described in detail with reference to the accompanying drawings.

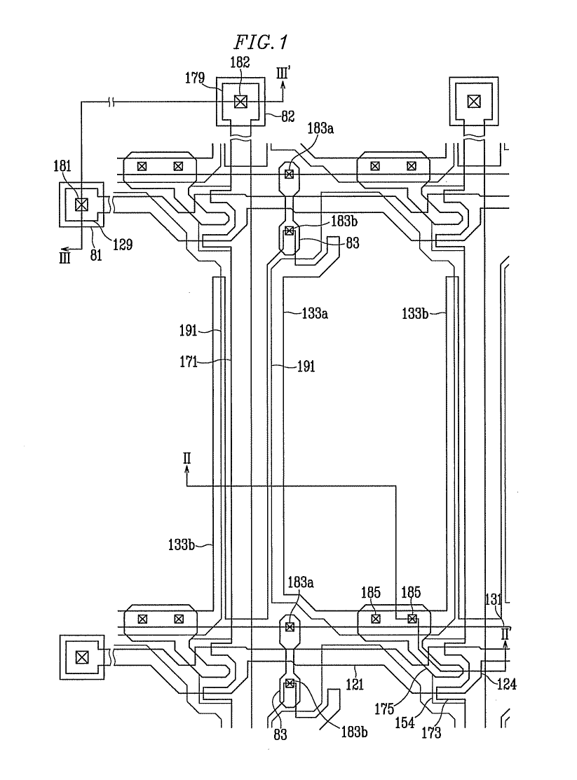

First, a TFT array panel according to an exemplary embodiment of the present invention will be described in detail with reference to FIG. 1 to FIG. 3.

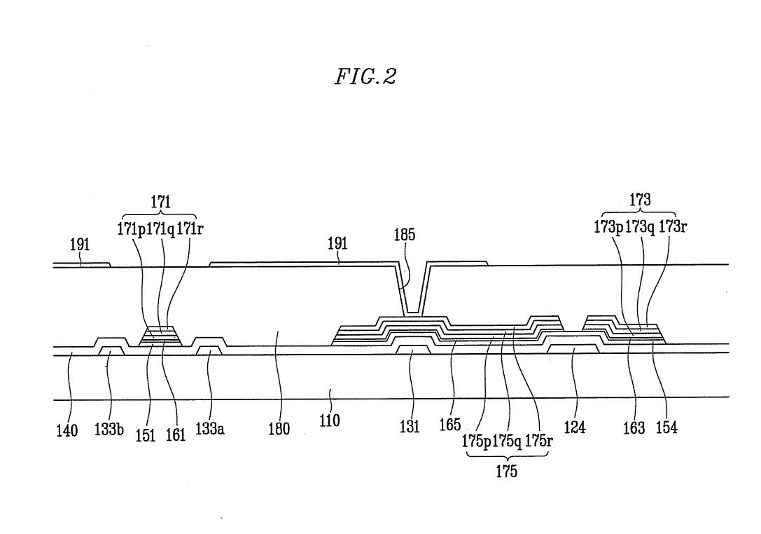

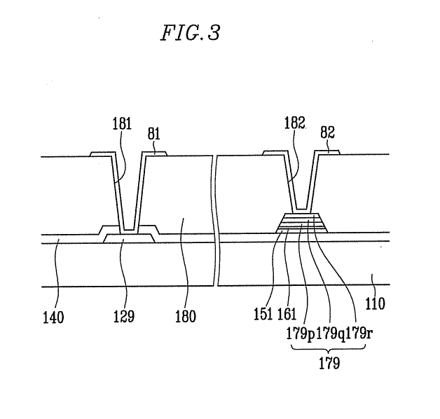

FIG. 1 is a layout view of a TFT array panel according to an exemplary embodiment of the present invention, and FIG. 2 and FIG. 3 are cross-sectional views of the TFT array panel shown in FIG. 1 taken along the line II-II′ and the line III-III′, respectively.

As shown particularly in FIG. 1, a plurality of gate lines 121 and a plurality of storage electrode lines 131 are formed on an insulating substrate 110, which is made of transparent glass or plastic, for example. The gate lines 121, configured for transmitting gate signals, extend substantially in a transverse direction. Each gate line 121 includes a plurality of gate electrodes 124 that protrude downward, and an end portion 129 having a large area for connection with another layer or an external driving circuit. A gate driving circuit (not shown) for generating gate signals may be mounted on a flexible printed circuit film (not shown) which is attached to the substrate 110. Alternatively, the gate driving circuit may be directly mounted on the substrate 110, or may be integrated into the substrate 110. When the gate driving circuit is integrated into the substrate 110, the gate lines 121 may be extended so as to be directly connected thereto.

The storage electrode lines 131 are supplied with a predetermined voltage, with each of the storage electrode lines 131 including a stem extending substantially parallel to the gate line 121, and a plurality of pairs of storage electrodes 133a and 133b branching out from the stem. Each storage electrode line 131 is disposed between two neighboring gate lines 121, with the stem located nearer the lower one of the two gate lines 121. Each of the storage electrodes 133a and 133b includes a fixed terminal connected to the stem and a free terminal on the opposite side. The fixed terminal of a storage electrode 133a has a large area, and the free terminal of the storage electrode 133a is divided into two portions consisting of a straight portion and a crooked portion. However, the shape and disposition of the storage electrode line 131 may be embodied by several different configurations.

The gate lines 121 and the storage electrode lines 131 may be made of, for example, an aluminum (Al) containing metal such as Al and an Al alloy, a silver (Ag) containing metal such as Ag and a Ag alloy, a copper (Cu) containing metal such as Cu and a Cu alloy, a molybdenum (Mo) containing metal such as Mo and a Mo alloy, chromium (Cr), tantalum (Ta), or titanium (Ti). Alternatively, the gate lines 121 and the storage electrode lines 131 may have a multi-layered structure including two conductive layers (not shown) having different physical properties. One of the two conductive layers may be made of low resistivity metal such as an Al-containing metal, an Ag-containing metal, and a Cu-containing metal for reducing signal delay or voltage drop. The other conductive layer may be made of a material such as a Mo-containing metal, Cr, Ti, and Ta, which has good physical, chemical and electrical contact characteristics with other materials, particularly such as indium tin oxide “ITO” and indium zinc oxide “IZO”. Suitable examples of the combination of two layers include a pair of a lower Cr layer and an upper Al (alloy) layer and a pair of a lower Al (alloy) layer and an upper Mo (alloy) layer. However, the gate lines 121 and the storage electrode lines 131 may be made of many various metals or conductors besides the above.

The lateral sides of the gate lines 121 and the storage electrode lines 131 are inclined relative to a surface of the substrate 110, with an exemplary inclination angle thereof ranging from about 30 degrees to about 80 degrees.

A gate insulating layer 140, such as one made of silicon nitride (SiNₓ) or silicon oxide (SiOₓ) is formed on the gate lines 121 and the storage electrode lines 131.

A plurality of semiconductor stripes 151 of hydrogenated amorphous silicon (“a-Si”), for example, are formed on the gate insulating layer 140. Each semiconductor stripe 151 extends substantially in the longitudinal direction, and has a plurality of projections 154 branching out toward the gate electrodes 124. A plurality of ohmic contact stripes 161 and islands 165 are formed on the semiconductors 151. The ohmic contacts 161 and 165 are made of, for example, n+hydrogenated a-Si heavily doped with an n-type impurity such as phosphorus (P), or of silicide. Each ohmic contact stripe 161 has a plurality of projections 163, with a projection 163 and an ohmic contact island 165 disposed in pairs on a projection 154 of a semiconductor stripe 151.

The lateral sides of the semiconductor stripes 151 and the ohmic contacts 161 and 165 are also inclined relative to a surface of the substrate 110, with an exemplary inclination angle thereof ranging from about 30 degrees to about 80 degrees.

A plurality of data lines 171 and a plurality of drain electrodes 175 are formed on the ohmic contacts 161 and 165.

The data lines 171 configured for transmitting data signals extend substantially in the longitudinal direction and intersect the gate lines 121. Each data line 171 also intersects the storage electrode lines 131, and is disposed between neighboring sets of storage electrodes 133a and 133b. Each data line 171 includes a plurality of source electrodes 173 branching out toward the gate electrodes 124, and an end portion 179 having a large area for connection with another layer or an external driving circuit. The data driving circuit (not shown) for generating data signals may be mounted on a flexible printed circuit film (not shown) attached to the substrate 110. Alternatively, the data driving circuit may be directly mounted on the substrate 110, or integrated into the substrate 110. When the data driving circuit is integrated into the substrate 110, the data lines 171 may be extended so as to be directly connected to the data driving circuit.

Each drain electrode 175 is separated from the data line 171 and opposes a source electrode 173 with respect to a gate electrode 124. Each drain electrode 175 has an end portion having a large area, and another stick-shaped end portion. The end portion having a large area overlaps a storage electrode line 131, and the stick-shaped end portion is partially surrounded by a curved source electrode 173.

A gate electrode 124, a source electrode 173, and a drain electrode 175, along with a projection 154 of a semiconductor stripe 151, form a TFT having a channel formed in the projection 154 disposed between the source electrode 173 and the drain electrode 175.

As particularly illustrated in FIG. 2, the data lines 171 and the drain electrodes 175 have a triple-layered structure including a lower layer 171p and 175p, an intermediate layer 171q and 175q, and an upper layer 171r and 175r. The lower layer 171p and 175p may be made of a refractory metal such as Mo, Cr, Ta, Ti, or an alloy thereof, while the intermediate layer 171q and 175q may be made of an Al-containing metal, an Ag-containing metal, or a Cu-containing metal having low resistivity. The upper layer 171r and 175r may be made of a refractory metal or an alloy thereof having excellent contact characteristics with ITO or IZO. An example of the triple-layered structure includes a lower Mo (alloy) layer, an intermediate Al (alloy) layer, and an upper Mo (alloy) layer.

The data lines 171 and the drain electrodes 175 may have a double-layered structure including a lower refractory metal layer (not shown) and an upper layer (not shown) having low resistivity, or a single-layered structure made of a material among the above-mentioned various materials. An example of the double-layered structure includes a lower Cr or Mo (alloy) layer and an upper Al (alloy) layer. However, the data lines 171 and the drain electrodes 175 may be made of many various metals or conductive materials besides the above.

In FIG. 3, a similar designation is used to differentiate the triple layer structure for the end portion 179 of the data line 171. That is, 179p designates the lower layer of the end portion 179, 179q designates the intermediate layer of the end portion 179, and 179r designates the upper layer of the end portion 179.

The lateral sides of the data lines 171 and the drain electrodes 175 are also inclined relative to a surface of the substrate 110, with exemplary inclination angles thereof in a range of about 30 degrees to about 80 degrees.

The ohmic contacts 161 and 165 are interposed only between the underlying semiconductor stripes 151 and the overlying data lines 171 and the drain electrodes 175 thereon, and reduce the contact resistance therebetween.

Except for the channel region between the source electrodes 173 and drain electrodes 175, the semiconductor stripes 151 and ohmic contact layers 161 and 165 have substantially the same planar shape as the data lines 171 and the drain electrodes 175. That is, the layer of the semiconductor stripes 151 is always formed under the data lines 171 and the drain electrodes 175 as well as the underlying ohmic contact layers 161, 163, and 165, and also exists between source electrodes 173 and drain electrodes 175, which are exposed. However, due to practical problems in the fabrication process, the semiconductor stripes 151 and the ohmic contact layer 161, 163, and 165 protrude further than the data lines 171 and the drain electrodes 175, which may cause an after-image and a waterfall effect.

A passivation layer 180 is formed on the data lines 171, the drain electrodes 175, and the exposed portions of the semiconductors 154.

The passivation layer 180 may be made of an inorganic insulator such as silicon nitride or silicon oxide, an organic insulator, or a low dielectric insulator. The organic insulator and the low dielectric insulator have dielectric constants of about 4.0 or less. Suitable examples of low dielectric insulators include a-Si:C:O and a-Si:O:F formed by plasma enhanced chemical vapor deposition (PECVD). The passivation layer 180 may also be made of a photosensitive organic insulator, with the surface thereof being flat. However, the passivation layer 180 may also have a double-layered structure including both a lower inorganic layer and an upper organic layer so as to prevent harm to the exposed portions of the semiconductors 151 and to make the most of the excellent insulating characteristics of the organic layer.

The passivation layer 180 has a plurality of contact holes 182 and 185 exposing the end portions 179 of the data lines 171, and the drain electrodes 175, respectively. The passivation layer 180 and the gate insulating layer 140 also have a plurality of contact holes 181 exposing the end portions 129 of the gate lines 121 and a plurality of contact holes 183a and 183b exposing portions of the storage electrode lines 131 near the fixed terminals of the storage electrodes 133a and 133b or portions of the free terminals.

A plurality of pixel electrodes 191, a plurality of overpasses 83, and a plurality of contact assistants 81 and 82 are formed on the passivation layer 180. These elements may be made of a transparent conductive material such as ITO and IZO, or a reflective metal such as Al, Ag, or an alloy thereof.

The pixel electrode 191 is physically and electrically connected with the drain electrode 175 through the contact hole 185, and is supplied with a data voltage from the drain electrode 175. The pixel electrode 191 supplied with a data voltage generates an electric field in cooperation with a common electrode (not shown) on the opposite panel (not shown) that is supplied with a common voltage so that the orientations of LC molecules in an LC layer (not shown) interposed between the two electrodes are determined. A pixel electrode 191 and the common electrode form a capacitor (hereinafter referred to as an “LC capacitor”) to store and preserve the applied voltage even after the TFT is turned off.

The pixel electrode 191 overlaps the storage electrode line 131, including the storage electrodes 133a and 133b. The pixel electrode 191 and the drain electrode 175 electrically connected with the pixel electrode 191, overlap the storage electrode line 131 to form a capacitor referred to as a “storage capacitor”, which enhances the voltage storing capacity of the LC capacitor.

The contact assistants 81 and 82 are connected to the end portion 129 of the gate line 121 and the end portion 179 of the data line 171 through the contact holes 181 and 182, respectively. The contact assistants 81 and 82 supplement the adhesive property of the end portions 179 and 129 of the data lines 171 and the gate lines 121 to exterior devices, thus protecting the same.

The overpass 83 traverses the gate line 121, and is connected to the exposed portion of the storage electrode line 131 and the exposed end portion of the free terminal of the storage electrode 133a through a pair of contact holes 183a and 183b, which are disposed opposite each other with respect to a gate line 121 therebetween. The storage electrode lines 131 including the storage electrodes 133a and 133b, along with the overpasses 83, may be used to repair any defect of the gate lines 121, the data lines 171, or the TFTs.

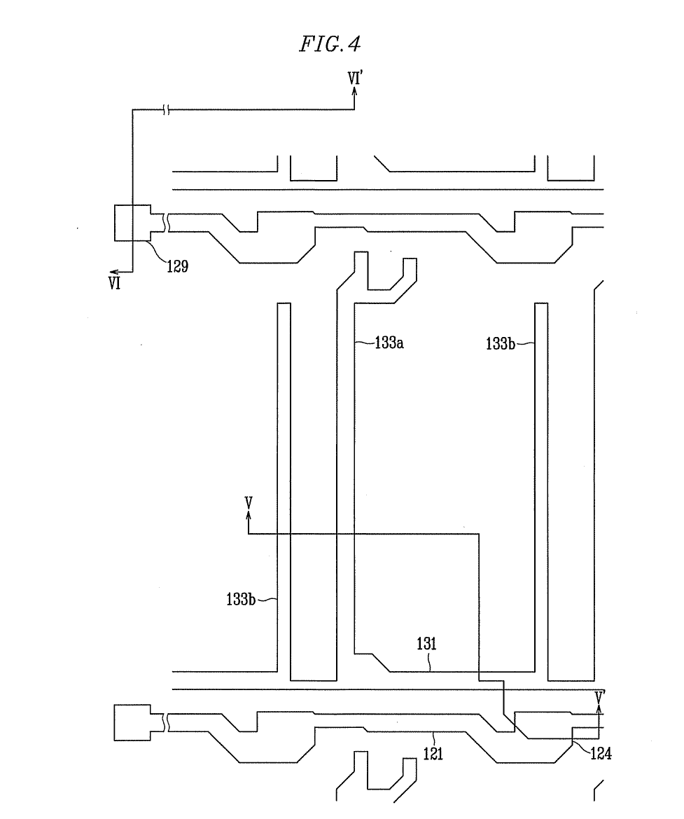

A manufacturing method of the TFT array panel shown in FIG. 1 to FIG. 3 will now be described in detail with reference to FIG. 4 to FIG. 22.

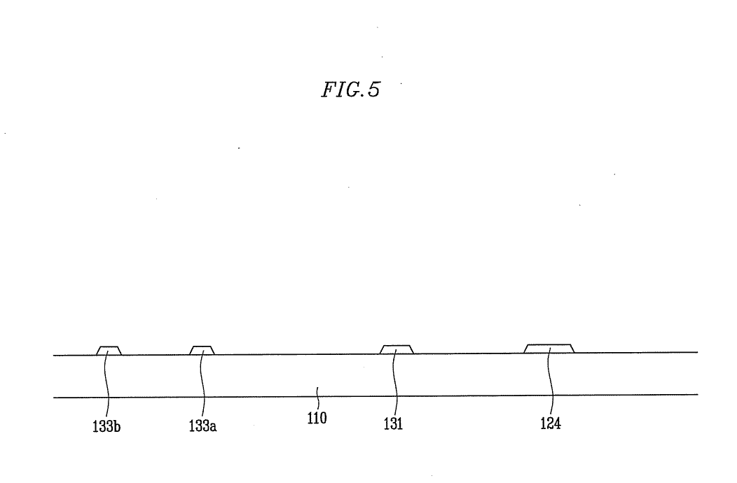

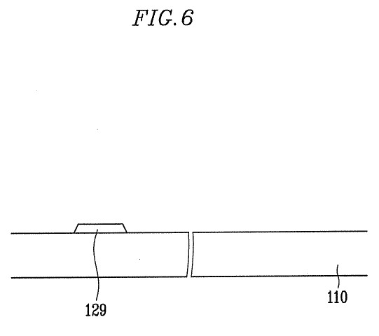

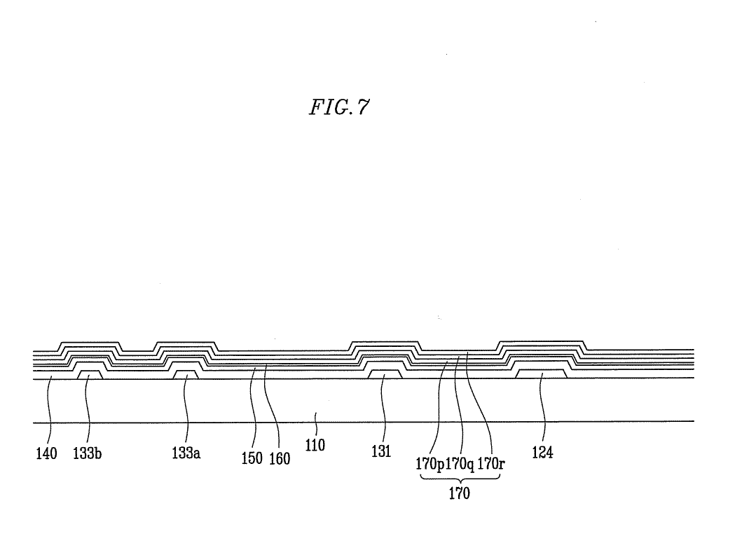

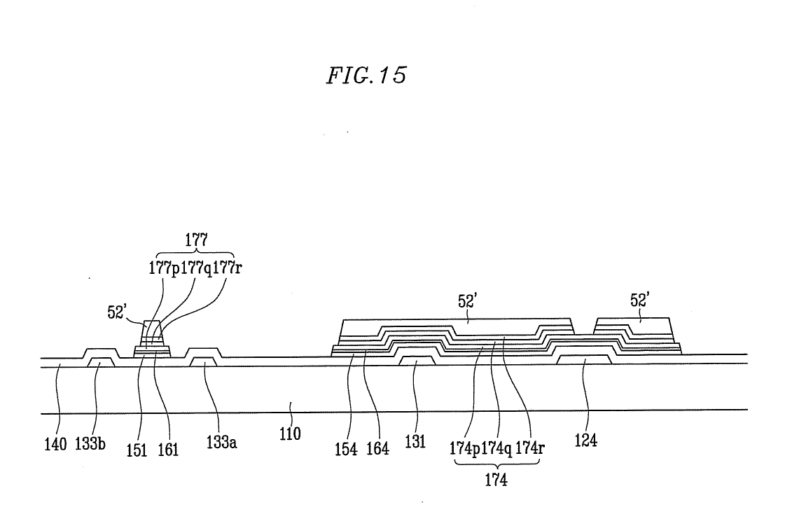

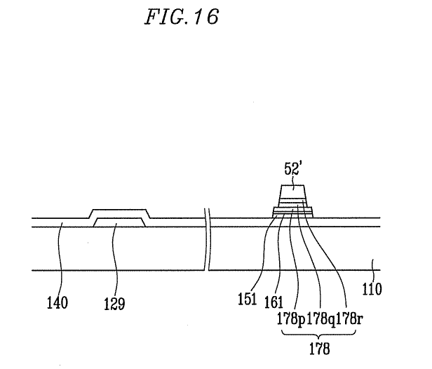

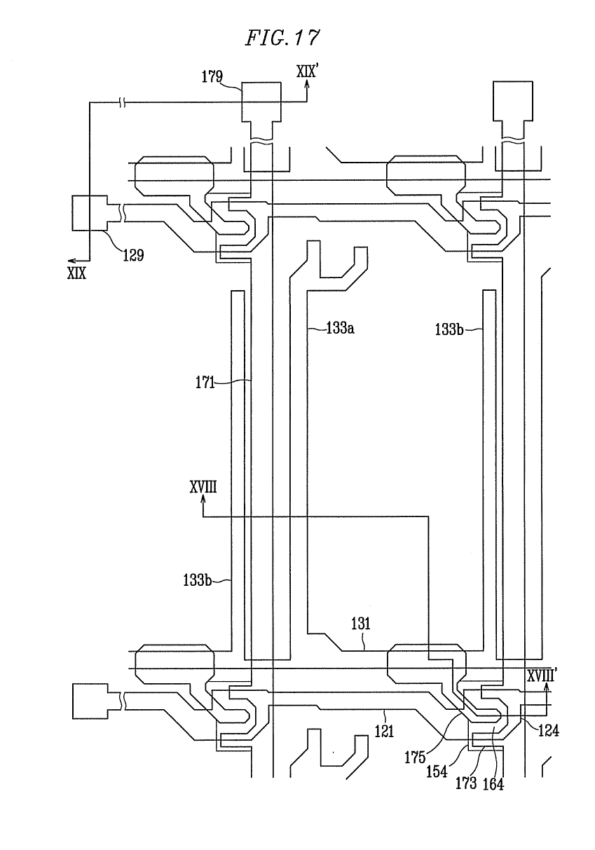

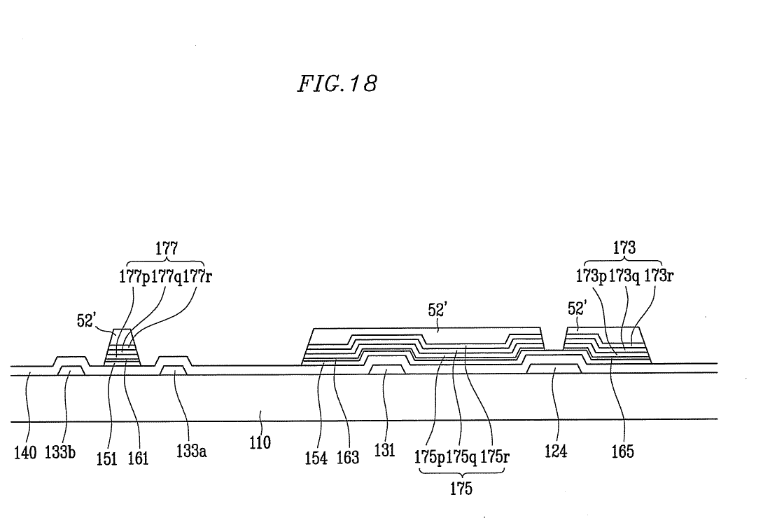

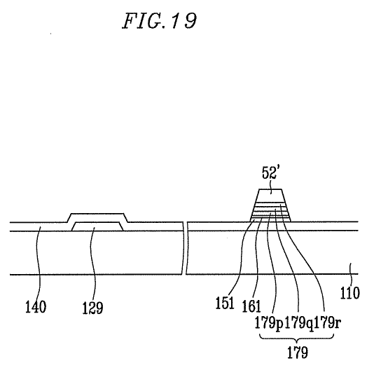

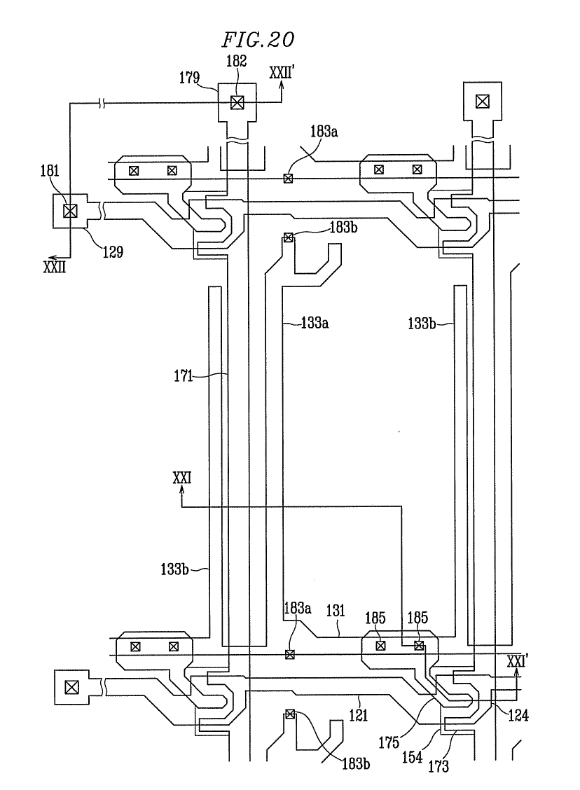

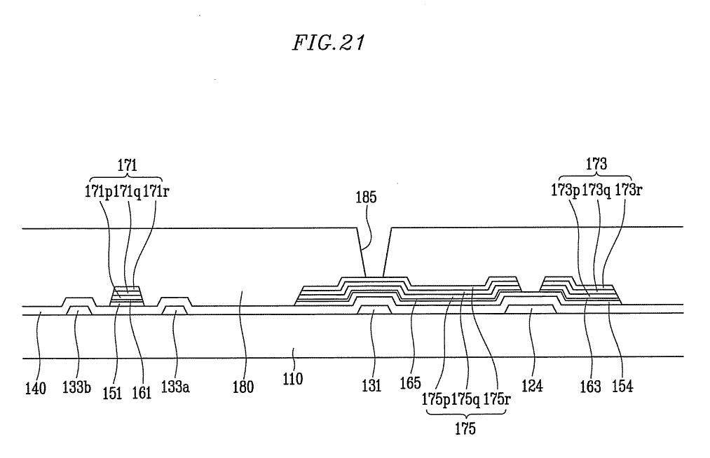

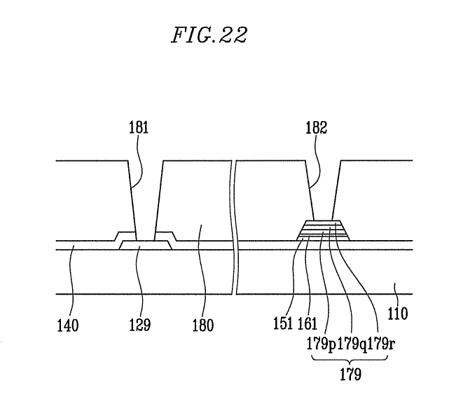

FIG. 4 is a layout view of the TFT array panel shown in FIG. 1 in an intermediate step of a manufacturing method thereof according to an exemplary embodiment of the present invention, and FIG. 5 and FIG. 6 are cross-sectional views of the TFT array panel shown in FIG. 4 taken along the line V-V′ and the line VI-VI′, respectively. FIG. 7 to FIG. 16 are cross-sectional views sequentially illustrating steps following the step shown in FIG. 4 to FIG. 6 of the manufacturing method of the TFT array panel, and FIG. 17 is a layout view of the TFT array panel in a step following the step shown in FIG. 15 and FIG. 16. FIG. 18 and FIG. 19 are cross-sectional views of the TFT array panel shown in FIG. 17 taken along the line XVIII-XVIII′ and the line XIX-XIX′, FIG. 20 is a layout view of the TFT array panel in a step following the step shown in FIG. 17 to FIG. 19, and FIG. 21 and FIG. 22 are cross-sectional views of the TFT array panel shown in FIG. 20 taken along the line XXI-XXI′ and the line XXII-XXII′.

First, as shown in FIG. 4 to FIG. 6, a plurality of gate lines 121, including gate electrodes 124 and end portions 129, and a plurality of storage electrode lines 131, including storage electrodes 133a and 133b, are formed on an insulating substrate 110 such as one made of transparent glass or plastic, for example.

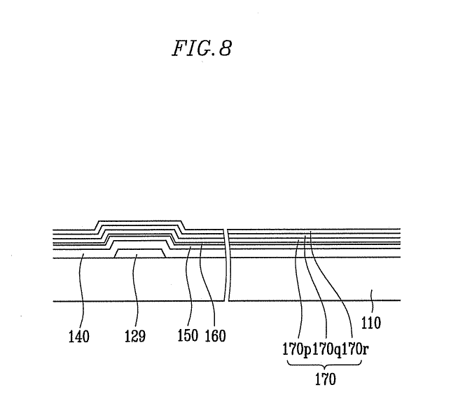

Then, as shown in FIG. 7 and FIG. 8, a gate insulating layer 140 made of, for example, SiNₓ, an undoped intrinsic a-Si layer 150, and an a-Si layer 160 doped with an impurity (e.g., n+a-Si) are formed on the gate lines 121 and the storage electrode lines 131 by PECVD. The intrinsic a-Si layer 150 is formed of hydrogenated amorphous silicon and the like, and the a-Si layer 160 doped with an impurity is formed of a-Si heavily doped with an n-type impurity such as P, or of silicide.

Successively, a data conductive layer 170 is formed on the doped a-Si layer 160. In the embodiment illustrated, the data conductive layer 170 includes a lower layer 170p made of a material including Mo, an intermediate layer 170q made of a material including Al, and an upper layer 170r made of a material including Mo.

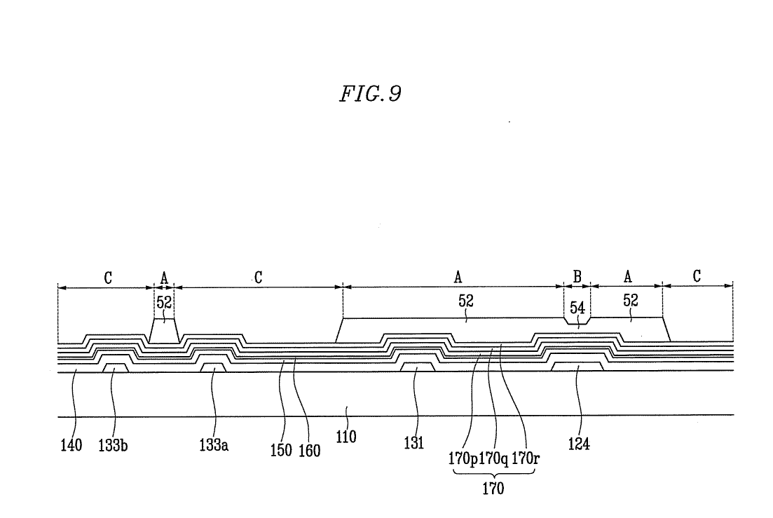

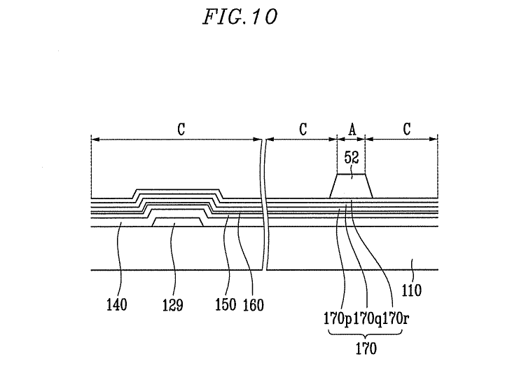

Then, as shown in FIG. 9 and FIG. 10, a photosensitive film is coated on the upper layer 170r of the data conductive layer 170, and is subsequently exposed to light and developed to form a first photosensitive film pattern 52 and 54. The first photosensitive film pattern 52 and 54 includes thick portions 52 and thin portions 54.

For convenience of description, the data conductive layer 170 along with the doped a-Si layer 160 and the intrinsic a-Si layer 150 where wiring will subsequently be formed is referred to as a wiring portion A; the portion where the channel will subsequently be formed on the gate electrode 124 is referred to as a channel portion B; and the remaining portion not including the wiring portion A and the channel portion B is referred to as a remaining portion C.

In the first photosensitive film pattern 52 and 54, the thick portion 52 located at the wiring portion A is formed to be thicker than the thin portion 54 located at the channel portion B, while the photosensitive film at the remaining portion C is completely removed. The thickness ratio of the thick portion 52 to the thin portion 54 is established depending on the process conditions in an etching process that will be described later.

The position-dependent thickness of the photosensitive film is obtained by several techniques, such as for example by providing semi-transparent areas as well as transparent areas and light blocking areas on the exposure mask. The semi-transparent areas alternatively have a slit pattern or a lattice pattern, or are a thin film with intermediate transmittance or intermediate thickness. When using a slit pattern, the width of the slits or the distance between the slits may be smaller than the resolution of a light exposure tool used for the photolithography.

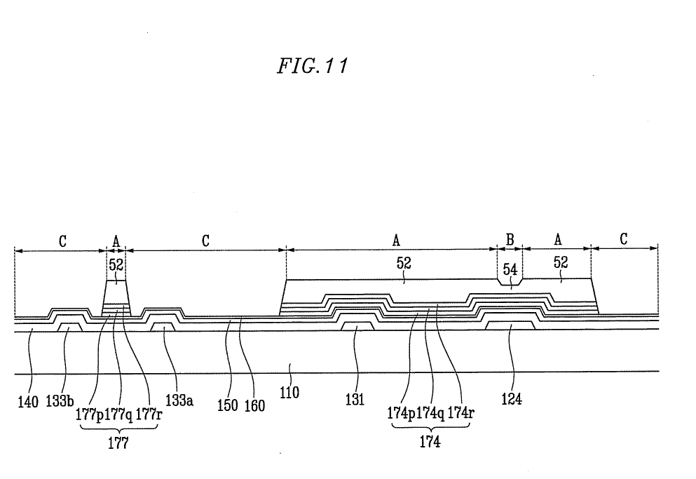

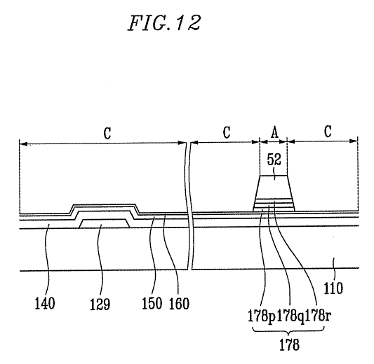

Subsequently, as shown in FIG. 11 and FIG. 12, the substrate 110 is loaded in a chamber (not shown), and the exposed portions of data conductive layer 170 corresponding to the remaining portions C are dry etched with a fluorine-based gas such as sulfur hexafluoride (SF₆) using the first photosensitive film pattern 52 and 54 to form data patterns 174 and 178.

In FIG. 11 and FIG. 12, for the data patterns 174 and 178, the subscript “p” is used for the lower layer, the subscript “q” for the intermediate layer, and the subscript “r” for the upper layer.

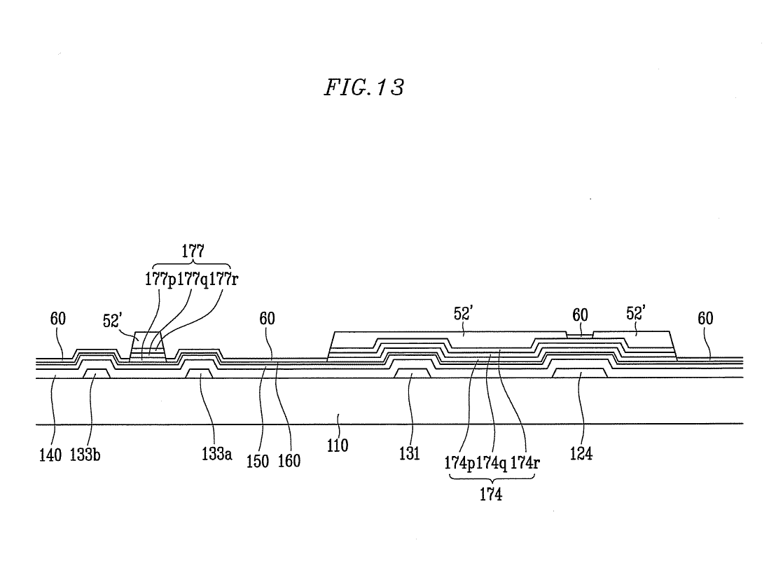

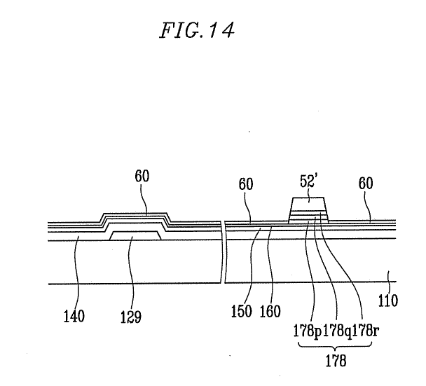

Next, as shown in FIG. 13 and FIG. 14, the gas in the chamber (not shown) is exhausted. Then, oxygen (O₂) gas is introduced into the chamber, and an oxygen plasma process is performed to remove the thin portions 54 of the first photosensitive film pattern 52 and 54 located at the channel portion B. As a result, the thick portions 52 of the first photosensitive film pattern 52 and 54 are also partially removed by as much as the thickness of the thin portions 54 to form a second photosensitive film pattern 52′. Also, as this oxygen plasma process is progressed, an oxide film 60 is formed on the surface of the doped a-Si layer 160 and the data conductive layer 174 that are exposed on the substrate 110.

Then, as shown in FIG. 15 and FIG. 16, the gas in the chamber (not shown) is exhausted. Then, a fluorine-based gas, including SF₆ gas and a chlorine-based gas, including chlorine (Cl₂) gas or hydrogen chloride (HCl) gas, are introduced into the chamber (not shown). The SF₆ gas and the Cl₂ or HCl gas may be used as an etching gas for the upper layers 174r and 178r of the data patterns 174 and 178 (made of Mo, for example), and boron trichloride (BCl₃) gas and Cl₂ gas or HCl gas may be used as an etching gas for the intermediate layers 174q and 178q of the data patterns 174 and 178 (made of Al, for example). As a carrier gas for facilitating the etching process, a gas mixture of two or more selected from a group consisting of helium (He) gas, neon (Ne) gas, and oxygen (O₂) gas may be additionally used.

In this manner, by using an etching gas and a carrier gas introduced into a chamber, both the doped a-Si layer 160 and the intrinsic a-Si layer 150 that are exposed to the remaining portion C are dry etched with the second photosensitive film pattern 52′ as a mask, thereby forming a doped a-Si layer pattern 164 and an intrinsic semiconductor layer 154. In so doing, the oxide film 60 formed on the data conductive layer 174 is also removed.

In this process, the second photosensitive film pattern 52′ is removed to a certain extent as the doped a-Si layer 160 and the intrinsic a-Si layer 150 are etched, and accordingly, the upper layers 174r and 178r of the data patterns 174 and 178 are exposed. The exposed upper layers 174r and 178r of the data patterns 174 and 178 are removed together with the doped a-Si layer 160 and the intrinsic a-Si layer 150. As the upper layer 170r is removed, the exposed intermediate layers 174q and 178q of the data patterns 174 and 178 are also removed.

Then, the gases in the chamber (not shown) are exhausted. BCl₃ gas and a chlorine-based gas, including Cl₂ gas or HCl gas, are then introduced into the chamber (not shown). These gases are used for removing the intermediate layers 174q and 178q of the data patterns 174 and 178 (made of Al, for example) and the lower layers 174p and 178p of the data patterns 174 and 178 (made of Mo, for example). As a carrier gas for facilitating the etching process, a mixed gas of two or more selected from a group consisting of He gas, Ne gas, and O₂ gas may be additionally used. Through this process, the intermediate layer 174q and the lower layer 174r of the data pattern 174 exposed to the channel portion B are removed.

In this manner, by using an etching gas and a carrier gas introduced into the chamber and the second photosensitive film pattern 52′ as a mask, as shown in FIG. 17 to FIG. 19, the data patterns 174 and 178 exposed to the channel portion B are removed to form a source electrode 173 and a drain electrode 175. In the illustrated embodiment, the source electrode and the drain electrode 173 and 175 have a normally tapered configuration such that the cross section area thereof decreases gradually to the top.

Then, the doped a-Si layer 164 at the channel portion B is removed by etching, after which the second photosensitive film pattern 52′ is removed.

In conventional processing, the substrate 110 is loaded into different chambers, and the data conductive layer 170, the doped a-Si layer 160, and the intrinsic a-Si layer 150 are wet or dry etched with a mask to be patterned, thereby forming data lines 171 and semiconductors 151. Such process steps are complicated, and the associated process time is long.

However, in the present invention embodiments, the substrate 110 is loaded in a chamber, and the data conductive layer 170, the doped a-Si layer 160, and the intrinsic a-Si layer 150 are dry etched with a mask to form data lines 171 and semiconductors 151. Accordingly, the process is simplified so that the process time as well as the cost of products can be reduced.

Additionally, in the prior art, the process of forming the second photosensitive film pattern 52′ by ashing the first photosensitive film pattern 52 so that the channel portion B is exposed was performed after patterning both the data conductive layer 170 and the Si layers 150 and 160. Due to this ashing process, a natural oxide film 60 is formed on the surface of the exposed film. This natural oxide film 60 causes an incomplete removal of the data patterns 174 and 178 as the data patterns 174 and 178 positioned at the channel portion B are etched, such that a short circuit between the source electrode 173 and the drain electrode 175 could be generated.

On the other hand, in the present invention embodiments, after forming the data patterns 174 and 178 by patterning the data conductive layer 170 and ashing the first photosensitive film pattern 52 and 54 so that the channel portion B is exposed, patterning of the Si layers 150 and 160 is performed. Consequently, according to the present invention embodiments, the natural oxide film 60 formed by the ashing process of the first photosensitive film pattern 52 and 54 is removed when the Si layers 150 and 160 are patterned, and as a result, a short circuit between the source electrode 173 and the drain electrode 175 can be prevented. Therefore, the quality of a display device can be improved.

Then, as shown in FIG. 20 to FIG. 22, a passivation layer 180 is formed on the gate insulating layer 140, the end portions 129 of the gate lines 121, and the data lines 171 and drain electrodes 175. In the illustrated embodiment, the passivation layer 180 is made of an inorganic insulator such as, for example SiNₓ and SiOₓ. However, the passivation layer 180 may include a lower passivation layer made of an inorganic insulator and an upper passivation layer made of an organic insulator, or the passivation layer 180 may also be formed solely of an organic insulator. The organic insulator for the upper passivation layer may have photosensitivity, with an exemplary dielectric constant thereof lower than about 4.0.

As described above, since the data lines 171 including the source electrodes 173 and the drain electrodes 175 have a normally tapered configuration, the profile of the passivation layer 180 can be made smooth. Accordingly, adhesiveness between the passivation layer 180 and the data lines 171 including the source electrodes 173 and the drain electrodes 175 is improved such that the wiring is prevented from being short circuited.

Subsequently, the passivation layer 180 is etched to form a plurality of contact holes 181, 182, and 183a exposing the end portions 129 of the gate lines 121, the end portions 179 of the data lines 171, and portions of the storage electrode lines 131 near the fixed terminals of the storage electrode 133a. A plurality of contact holes 183b expose the straight portions of the free terminals of the storage electrodes 133a, and contact holes 185 expose the drain electrodes 175.

Finally, as shown in FIG. 1 to FIG. 3, a transparent conductive material such as ITO or IZO is deposited by sputtering on the passivation layer 180 and then patterned to form pixel electrodes 191, contact assistants 81 and 82, and overpasses 83.

According to the present invention embodiments, a data conductive layer, an a-Si layer doped with an impurity, and an intrinsic a-Si layer are dry etched in a chamber using a mask to form data lines and a semiconductor layer. Accordingly, the process time is reduced due to the simplified process, and the cost of a product may be reduced.

Also, according to the present invention embodiments, after patterning the data conductive layer and ashing the photosensitive film mask so that the conductive layer at the channel portion is exposed, patterning of the Si layer is performed. Accordingly, a natural oxide film having been formed during the ashing process is removed together when the Si layer is patterned. Therefore, a short circuit between a source electrode and a drain electrode is prevented, thereby improving the quality of a display device.

Although preferred embodiments of the present invention have been described in detail hereinabove, it should be clearly understood that many variations and/or modifications of the basic inventive concepts herein taught, which may appear to those skilled in the present art, will still fall within the spirit and scope of the present invention, as defined in the appended claims.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method of manufacturing a thin film transistor array panel, the method comprising:
forming a gate line on a substrate;
sequentially forming a gate insulating layer, a semiconductor layer, and a conductive layer on the gate line;
forming a photosensitive film on the conductive layer;
forming a first photosensitive film pattern including a first region and a second region that has a lesser thickness than the first region by patterning the photosensitive film;
forming a data pattern by etching the conductive layer using the first photosensitive film pattern as a mask;
forming a second photosensitive film pattern by ashing the first photosensitive film pattern to partially remove the first photosensitive film by as much as the thickness of the second region;
forming a semiconductor pattern by etching the semiconductor layer using the second photosensitive film pattern as a mask; and
forming a source electrode and a drain electrode by etching the data pattern exposed in the second region of the second photosensitive film pattern.

2. The method of claim 1, wherein the first region comprises a region corresponding to the location of a subsequently formed a data wire.

3. The method of claim 1, wherein the second region comprises a region corresponding to the location of a channel of a subsequently formed thin film transistor.

4. The method of claim 1, wherein the conductive layer is dry etched using a fluorine-based gas including sulfur hexafluoride (SF₆).

5. The method of claim 1, wherein the ashing of the first photosensitive film pattern is performed through an oxygen (O₂) plasma process.

6. The method of claim 1, wherein the semiconductor layer is dry etched using a fluorine-based gas including sulfur hexafluoride (SF₆) gas and a chlorine-based gas including chlorine (Cl₂) gas or hydrogen chloride (HCl) gas.

7. The method of claim 6, wherein a gas mixture of two or more of helium (He) gas, neon (Ne) gas, and oxygen (O₂) gas is added as a carrier gas for facilitating the dry etching process.

8. The method of claim 1, wherein a gas mixture of a sulfur hexafluoride (SF₆) or boron trichloride (BCl₃) gas and a chlorine (Cl₂) or hydrogen chloride (HCl) gas is used, and a gas mixture of two or more of helium (He) gas, neon (Ne) gas, and oxygen (O₂) gas is used as a carrier gas in forming the semiconductor pattern.

9. The method of claim 1, further comprising:
forming a passivation layer on the gate insulating layer, the source electrode, and the drain electrode; and
forming a pixel electrode on the passivation layer.

10. A method of manufacturing a thin film transistor array panel, the method comprising:
forming a gate line on a substrate;
sequentially forming a gate insulating layer, an intrinsic semiconductor layer, and an impurity-doped semiconductor layer on the gate line;
sequentially forming a lower molybdenum (Mo) layer, an intermediate aluminum (Al) layer, and an upper molybdenum (Mo) layer on the impurity-doped semiconductor layer to form a triple-layered conductive layer;
forming a photosensitive film on the upper molybdenum (Mo) layer;
forming a first photosensitive film pattern including a first region and a second region that has a lesser thickness than the first region by patterning the photosensitive film;
forming a data pattern by etching the triple-layered conductive layer using the first photosensitive film pattern as a mask;
forming a second photosensitive film pattern by ashing the first photosensitive film pattern to partially remove the first photosensitive film by as much as the thickness of the second region;
forming an impurity-doped semiconductor pattern and an intrinsic semiconductor by etching the impurity-doped semiconductor layer and the intrinsic semiconductor layer using the second photosensitive film pattern as a mask;
forming a source electrode and a drain electrode by etching the data pattern exposed in the second region of the second photosensitive film pattern; and
forming a contact member layer by etching the impurity-doped semiconductor pattern.

11. The method of claim 10, wherein, in the step of etching the impurity-doped semiconductor layer and the intrinsic semiconductor layer, the upper molybdenum (Mo) layer that is exposed and constitutes the data pattern is removed.

12. The method of claim 11, wherein the aluminum (Al) layer disposed under the removed upper molybdenum (Mo) layer is removed.

13. The method of claim 10, wherein the first region comprises a region corresponding to the location of a subsequently formed data wire.

14. The method of claim 10, wherein the second region comprises a region corresponding to the location of a channel of a subsequently formed thin film transistor.

15. The method of claim 10, wherein the etching of the triple-layered conductive layer using the first photosensitive film pattern as a mask is performed with a fluorine-based gas including sulfur hexafluoride (SF₆) gas.

16. The method of claim 10, wherein the ashing of the first photosensitive film pattern is performed through an oxygen (O₂) plasma process.

17. The method of claim 10, wherein the etching of the impurity-doped semiconductor layer and the intrinsic semiconductor layer is performed by a dry etching process using a fluorine-based gas including sulfur hexafluoride (SF₆) gas and a chlorine-based gas including chlorine (Cl₂) gas or hydrogen chloride (HCl) gas.

18. The method of claim 17, wherein a gas mixture of two or more of helium (He) gas, neon (Ne) gas, and oxygen (O₂) gas is added as a carrier gas for facilitating the dry etching process.

19. The method of claim 10, wherein, a gas mixture of boron trichloride (BCl₃) gas and a chlorine (Cl₂) or hydrogen chloride (HCl) gas is used, and a gas mixture of two or more of helium (He) gas, neon (Ne) gas, and oxygen (O₂) gas is used as a carrier gas in t etching the data pattern.
